(19) United States
(12) Patent Application Publication
(10) Pub. No.: US 2020/0277695 A1
(43) Pub. Date: Sep. 3, 2020

(54) FLEXIBLE SURFACE PLASMON RESONANCE FILM

(71) Applicant: National University of Singapore, Singapore (SG)

(72) Inventors: Kaichen XU, Singapore (SG); Guannan WANG, Singapore (SG); Minghui HONG, Singapore (SG)

(21) Appl. No.: 16/500,857

(22) PCT Filed: Apr. 5, 2018
(86) PCT No.: PCT/SG2018/050173

§ 371 Date: Oct. 4, 2019

(30) Foreign Application Priority Data
Apr. 5, 2017 (SG) 10201702821S

(51) Int. Cl. C23C 14/20; G01N 21/65; C23C 14/58; B29C 55/04

(52) U.S. Cl. CPC C23C 14/20; G01N 21/658; G01J 3/44; B29C 55/04; C23C 14/5886

(57) ABSTRACT

A method of fabricating a flexible surface plasmon resonance, SPR, film, a method of performing Surface enhanced Raman Spectroscopy, SERS, a flexible surface plasmon resonance, SPR, film, and a SERS system. The method of fabricating a flexible SPR film comprises the steps of depositing a metal film on a ductile poly (ε-caprolactone), PCL-based film having a first length to form a composite PCL-based film; and stretching the composite PCL-based film such that the ductile PCL-based film undergoes an irreversible transformation to form the SPR film exhibiting a second length that is larger than the first length.

### FIELD OF INVENTION

The present invention relates broadly to a flexible surface plasmon resonance film and to a method of fabricating the same.

### BACKGROUND

Any mention and/or discussion of prior art throughout the specification should not be considered, in any way, as an admission that this prior art is well known or forms part of common general knowledge in the field.

Flexible wearable sensors have been envisioned as promising diagnostic tools owing to their considerable applications in healthcare,^{[1,2]} protective equipment inspection,^{[3]} environmental monitoring^{[4]} and homeland security.^{[5]} In particular, to develop biocompatible and environmentally friendly biosensors is of paramount importance for their potential applications in wearable and point-of-care (POC) diagnostics to eliminate waste streams.^{[6-8]} Such biosensors built with biodegradable and biocompatible materials as backbone features can be integrated into living tissues as well as portable spectrometers for therapeutic and diagnostical purposes.^{[8,9]} Among a variety of biosensors, surface enhanced Raman scattering (SERS), an accurate label-free and finger-print detection means, is emerging as one of the most cutting-edge techniques for non-invasively tracing extremely low-concentration molecules.^{[10]} Primarily based on localized surface plasmon resonances (LSPRs), SERS is capable of enhancing excitated photons as well as vibrational scattering of analytic molecules via the amplification of electromagnetic (EM) fields, which relies on localizing light into the nanoscale volumes.^{[11,12]} Although tremendous advances have been made in demonstrating plenty of SERS substrates with sub-10 nm gap structures to allow the identification of finger-print information of probe molecules adsorbed on plasmonic nanostructures, most traditional approaches either based on chemical syntheses or complex lithographic methods, such as focused ion beam and electron beam lithography, suffer from nonuniformity or low throughput issues.^{[13,14]}

Furthermore, conventional SERS substrates employ rigid materials without biodegradability, such as glass and silicon as building blocks, which require to extract objective analytes and then be adsorbed onto the hard plasmonic templates for detection.^{[15]} In order to satisfy the requirement of increasingly demanded POC diagnostics for non-laboratory settings' monitoring, the in-situ detection approach is more preferred for practical applications, where the SERS substrates are directly attached onto the sample surfaces of interest.^{[16]} However, due to the lack of flexibility, the rigid SERS substrates have poor conformal contact with objects, especially those with complex topological shapes. On the other hand, because of the demand to excitate incident photons and then collect Raman signals from the back side of the SERS substrates for in-situ detection, high transparency of flexible substrates needs to be achieved.^{[17]}

To overcome these limitations, flexible SERS substrates are recently proposed to be a promising candidate. Numerous materials, such as adhesive tape, filter paper and polymers, have been applied as frameworks of the flexible SERS substrates. It still remains a long-standing challenge on how to simultaneously integrate the features of biodegradability, uniformity and batch-fabrication into the flexible SERS systems to satisfy the general requirement of POC diagnostics.

Y. Zhao, H. Chu, “Flexible surface enhanced Raman spectroscopy (SERS) substrates, methods of making, and methods of use,” (US 2011/0037976 A1) describes flexible SERS substrates, but the materials are based on plastic (polyethylene terephthalate (PET), polyether sulfone (PES), polyethylene naphthalate (PEN), polycarbonate (PC), nylon, polyether etherketone (PEEK), polysulfone (PSF), polyether imide (PEI), polyallylate (PAR), polybutylene terephthalate), which are not biocompatible and biodegradable.

J. Chen, Y. Huang, P. Kaman, L. Zhang, Z. Lin, J. Zhang, T. Chen, and L. Guo, “Flexible and adhesive surface enhance Raman scattering active tape for rapid detection of pesticide residues in fruits and vegetables,” (Analytical Chemistry 88, 2149-2155 (2016)) describes a concept of “paste and peel off”, which employs a commercial tape for efficient extraction of analytes on arbitrary surfaces. However, the uniformity of the plasmonic structures is not well considered and the adhesive tape is a non-biodegradable material, which violates the goal for environmental protection and sustainability.

K H. Kang, C. J. Heo, H. C. Jeon, S. Y. Lee, and S. M. Yang, “Durable plasmonic cap arrays on flexible substrate with real-time optical tunability for high-fidelity SERS devices,” (ACS Applied Materials & Interfaces 5, 4569-4574 (2013)) describes a stretchable polymer Polydimethylsiloxane (PDMS) employed as a building block. Relying on their elastic deformation property, it is possible to actively control the nanogap distance between metallic nanoparticles on their elastic and stretchable polymer films, which enables the reversible plasmonic spectral shift. However, the PDMS described faces enormous challenges to exactly control the optical properties of the plasmonic film under an external strain to reversibly deform the substrate in practical applications.

Embodiments of the present invention seek to address at least one of the above problems.

### SUMMARY

In accordance with a first aspect of the present invention, there is provided a method of fabricating a flexible surface plasmon resonance, SPR, film comprising the steps of depositing a metal film on a ductile poly (ε-caprolactone), PCL-based film having a first length to form a composite PCL-based film; and stretching the composite PCL-based film such that the ductile PCL-based film undergoes an irreversible transformation to form the SPR film exhibiting a second length that is larger than the first length.

In accordance with a second aspect of the present invention, there is provided a method of performing Surface enhanced Raman Spectroscopy, SERS, comprising using the SPR film fabricated from the method of the first aspect as a SERS substrate.

In accordance with a third aspect of the present invention, there is provided a flexible surface plasmon resonance, SPR, film comprising a metal film on a ductile poly (ε-caprolactone), PCL-based film; and wherein the ductile PCL-based film is in an irreversible transformation state in which a length of the ductile PCL-based film is enlarged compared to an unstretched state in which the metal film was deposited onto the ductile PCL-based film.

In accordance with a fourth aspect of the present invention, there is provided a Surface enhanced Raman Spectroscopy, SERS, system comprising the SPR film of the third aspect as a SERS substrate.

Embodiments of the present invention provide a method of fabricating a flexible surface plasmon resonance (SPR) film by uniaxially stretching metal decorated PCL polymer film, which is a bio-degradable and bio-compatible polymer film. This composite film after stretching shows interesting phenomena: three dimensional and periodic wave-shaped micro-ribbons array embedded with a high density of nanogaps functioning as hot-spots at an average gap size of 20 nm and nanogrooves array along the stretching direction. The stretched polymer surface plasmon resonance film gives rise to more than 10 times signal enhancement in comparison with that of the unstretched composite film. The polymer SPR film with excellent flexibility and transparency can be conformally attached onto arbitrary non-planar surfaces for in-situ detection of various chemicals.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIGS. 1(a) to (d) show schematic diagrams illustrating the process of stretching polymer SPR film under an external mechanic force, according to an example embodiment.

FIGS. 2(a) to (d) show experimental data illustrating the surface morphology of stretched polymer SPR film without and with 25 nm Ag film, according to an example embodiments.

FIGS. 3. (a) to (d) are schematic diagrams illustrating proposed models of nanostructures' formation via stretching polymer SPR film, according to an example embodiment.

FIGS. 3(e) and (f) show calculated electric field distributions of the micro-ribbons and nanogrooves, respectively, according to an example embodiment.

FIGS. 4(a) to (c) show SERS spectra of 4-MBT molecules adsorbed on polymer SPR film with different thicknesses of Ag films before and after the stretching, according to example embodiments.

FIGS. 5(a) and (b) show photographs of a flexible polymer SPR film for practical SERS applications, according to example embodiments.

FIG. 5(c) shows a schematic diagram of contacting polymer SPR film onto the green mussel and collecting the SERS signals from the back side surface, according to an example embodiments.

FIG. 5(d) shows experimental data of in-situ detection of MG molecules on the green mussel surface at various concentrations from 10 mM to 1 μM, according to example embodiments.

FIGS. 6(a) to (d) show experimental data illustrating the surface morphology of the polymer SPR films deposited with Ag (thickness: 25 nm), according to an example embodiment.

FIG. 7 shows transmission spectra of a PCL polymer film before and after the stretching, according to an example embodiment.

FIGS. 8 (a) to (d) show experimental data of the stretched polymer SPR film, according to an example embodiment.

FIGS. 9(a) to (d) show SEM images illustrating the surface morphology of various metallic materials deposited on the PCL polymer films, according to example embodiments.

FIGS. 10(a) to (f) show SEM images of polymer SPR illustrating the mechanisms explanation. during stretching of a Ag film on PCL polymer film, according to an example embodiment.

FIGS. 11(a) and (b) shows XRD and FTIR spectra, respectively, of the stretched and unstretched PCL polymer films, according to an example embodiment.

FIGS. 12(a) and (b) shows spectra illustrating the influence of thickness of Ag film on PCL polymer film (stretched and unstretched) on SERS performance, according to example embodiments.

FIGS. 13(a) to (d) show Micro-UV-VIS transmission spectra of polymer SPR films at different thicknesses of Ag films before and after the stretching, according to example embodiments.

FIGS. 14(a) to (d) show experimental data illustrating the influence of the stretching ratio of polymer SPR film on SERS performance, according to example embodiments.

FIG. 15 shows a flowchart illustrating a method of fabricating a flexible SPR film, according to an example embodiment.

FIG. 16 shows a schematic cross-sectional drawing illustrating a flexible SPR film according to an example embodiment

### DETAILED DESCRIPTION

Embodiments of the present invention provide a promising biodegradable and flexible polymer surface plasmon resonance (SPR) film for in-situ surface enhanced Raman scattering (SERS) detection. The flexible SERS film is fabricated by irreversibly stretching a metal-deposited poly (ε-caprolactone) (PCL) film, according to example embodiments. After the stretching, the polymer SPR film forms a three dimensional (3D) wave-shaped structure with micro-ribbons array embedded with ultra-high-density of nanogaps and nanogrooves, which function as hot-spots for SERS. The stretched polymer SPR film according to example embodiments exhibits good flexibility and high uniformity, which can be seamlessly attached onto any non-planar surfaces. Compared to the unstretched composite film, the stretched polymer SPR film gives rise to more than 10 times SERS signals' enhancement. The features of biodegradability and batch-fabrication of the polymer SPR film open great opportunities to integrate the flexible SERS substrates according to example embodiments with portable Raman spectrometers for in-situ detection and disposable applications, such as food safety evaluation, medical examinations, personal protective equipment, etc.

The composite film after stretching according to example embodiments shows surprising phenomena: three dimensional and periodic wave-shaped micro-ribbons array embedded with an ultra-high density of nanogaps functioning as hot-spots at an average gap size of 20 nm and nanogrooves along the stretching direction. The stretched polymer surface plasmon resonance film gives rise to more than 10 times signal enhancement in comparison with that of the unstretched composite film. Furthermore, the SERS signals with high uniformity exhibit good temperature stability. The SPR film according to example embodiments with excellent flexibility and transparency can be conformally attached onto arbitrary non-planar surfaces for in-situ detection of various chemicals. Example embodiments of the present invention can provide for next-generation flexible SERS detection means, as well as enabling its huge potentials towards green wearable devices for point-of-care diagnostics.

Example embodiments of the present invention can provide advances in practical SERS applications for one or more of the following reasons.

A PCL film, as an excellent flexible, biodegradable and biocompatible material with good transparency (˜90%) and temperature stability (9.62%), is for the first time employed as a building block for flexible SERS substrates according to example embodiments.

The uniaxial stretching of Ag/PCL composite film results in the formation of large-area periodical micro-ribbons with a high density of plasmonic nanogaps and V-shaped nanogrooves according to example embodiments, which can be tuned by flexibly varying the thickness of metallic film. These plasmonic nanogaps and nanogrooves confine incident light in the form of near-field evanescent waves, serving as hot-spots to enhance SERS signals. Compared to conventional methodologies to achieve nanogaps that rely on several complex and precise fabrication procedures, example embodiments of the present invention make use of plastic strain to induce increased distances between adjacent lamellaes within PCL crystals to create plentiful plasmonic nanogaps. Furthermore, different from the conventional methods, which apply FIB milling or photolithography with anisotropic etching to achieve V-shaped groove profiles,^{[30,31]} Example embodiments of the present invention can provide an approach for initiating a new route to produce periodical V-shaped nanogrooves array via laterally shrinking PCL crystals perpendicularly to the elongation direction.

The ultrathin (˜10 μm) polymer SPR film according to example embodiments can be intimately attached onto arbitrary topological surfaces for in-situ detection of analytes for POC diagnostics due to their high transparency and flexibility. The features of low-cost, biodegradability and batch-fabrication of the polymer SPR film open great opportunities to integrate the flexible SERS substrates according to example embodiments with portable Raman spectrometers in the applications of resource-limited settings. Furthermore, the stretching induced plasmonic nanostructures according to example embodiments present good temperature stability (9.62%) and uniformity (6.48%) of the detected SERS signals.

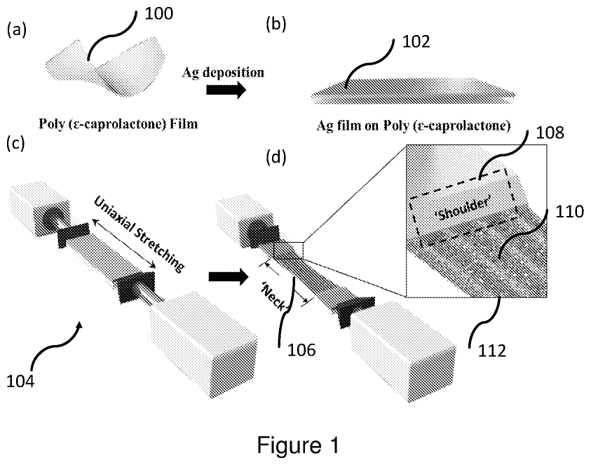

In one example embodiment, a flexible Poly (ε-caprolactone) (PCL) film 100 at a length of 9 cm, width 1 cm and thickness around 20 μm is deposited with a silver (Ag) film 102 by an electron-beam evaporator as shown in FIGS. 1 (a) and (b).

To deposit different thicknesses of Ag film on the PCL polymer, a BOC Edwards AUTO 306 electron-beam evaporator was employed in example embodiments. The vacuum was pumped down to 4.0˜5.0×10⁻⁶ Pa and the deposition rate was stabilized at 0.06 nm·s⁻¹. A quartz crystal oscillator was applied to monitor the film thickness. The deposition time determined the final thickness of Ag film. The fabrication procedures of other metallic thin films, including Au, Ni and Al, according to different embodiments were the same. To evaluate the stability of the films at a higher temperature, a heating panel was used to elevate environmental temperature, which was monitored by a temperature measurement sensor.

After fixing the Ag decorated PCL polymer film 100 onto a mechanical machine 104 for stretching, the efficient dimension of the Ag decorated PCL polymer film is set as 4 cm due to the fixation of the Ag decorated PCL polymer film at the both ends (FIG. 1 (c)). The Ag decorated PCL polymer film 100 is then subjected to uniaxial stretching from 4 cm to 10 cm under a constant velocity. Notably, in order to make the Ag decorated PCL polymer film form uniform nanostructures according to preferred embodiments, the stretching should be performed in the strictly uniaxial direction. Upon the stretching, the ductile Ag decorated PCL polymer film 100 firstly goes through a few percent (˜10%) of homogeneous uniaxial extension, followed by the formation of localized ‘neck’ 106 due to the mechanical instability of the Ag decorated PCL polymer film 100. The neck 106 region gradually expands and propagates via the spread of ‘shoulder’ 108 from the deformed region (neck 106 region) to undeformed region until the Ag decorated PCL polymer film 100 is entirely stretched to 10 cm (FIG. 1 (d)). This procedure involves plastic deformation, longitudinal elongation, transverse dimension's reduction as well as the thinning of the Ag decorated PCL polymer film 100. During the stretching, the deformation of the Ag decorated PCL polymer film 100 results in the formation of plentiful tiny cracks e.g. 110 inside the brittle Ag film 102. These cracks e.g. 110 are expected to serve as hot-spots to advantageously boost the SERS effect according to example embodiments. After the stretching, the thickness of Ag decorated PCL polymer film 100, hereinafter referred to as polymer SPR film, evolves from ˜20 μm to ˜10 μm.

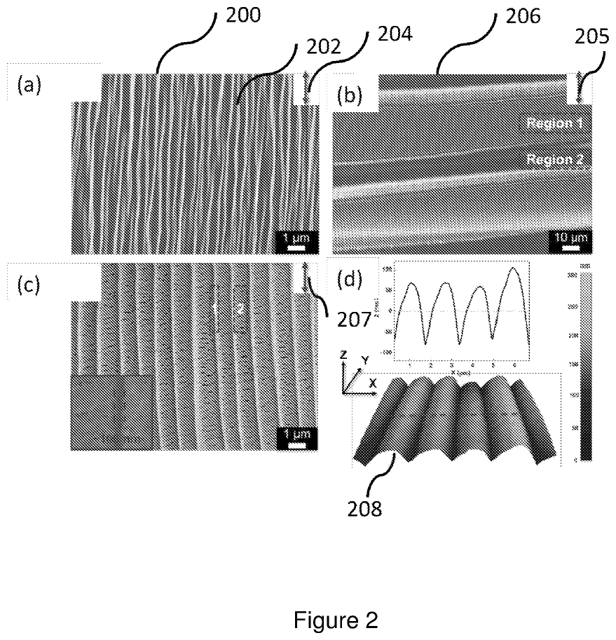

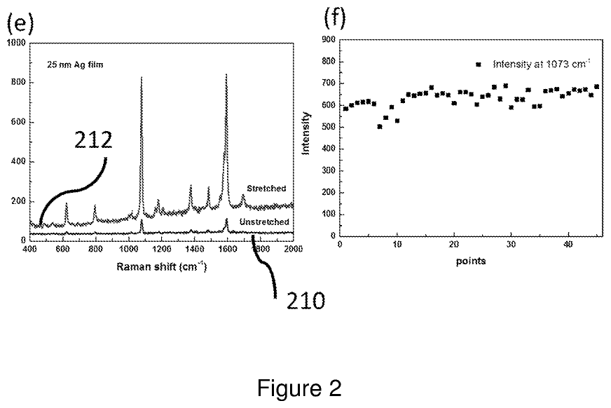

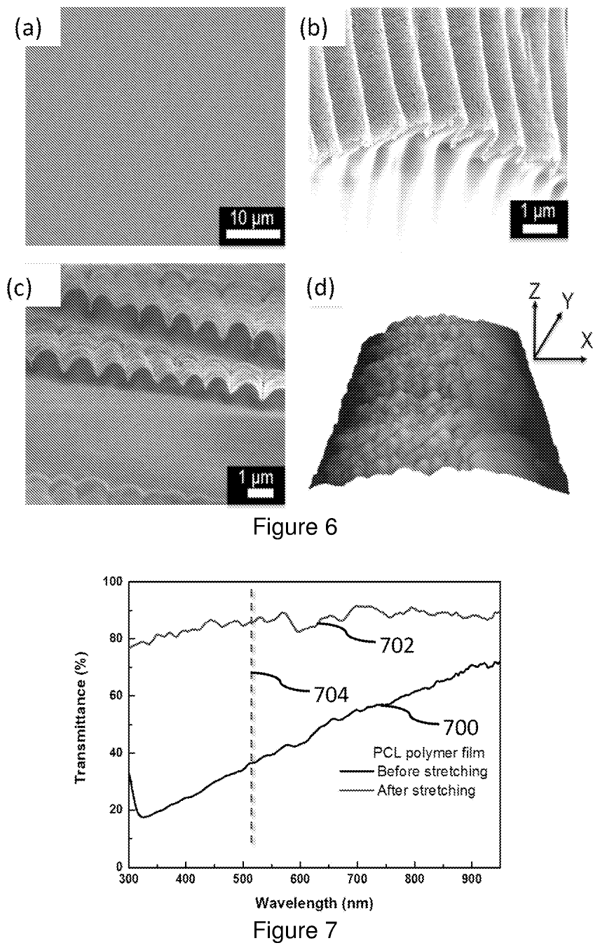

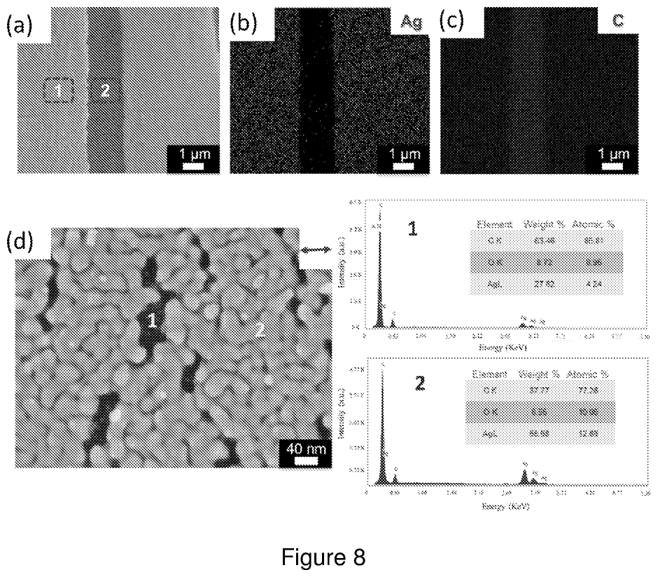

In order to untangle the surface morphology of the stretched polymer SPR film 112, firstly, the uniaxial stretched PCL polymer film 200 without Ag decoration is characterized by a scanning electron microscope (SEM). As can be seen in FIG. 2(a), the uniaxially stretched PCL films 200 are comprised of many highly oriented nanoridges e.g. 201 and nanogrooves e.g. 202 along the stretching direction 204, which are not observed on the unstretched PCL films. Additional surface morphology investigations will be described below with reference to FIG. 6. It is worthwhile to note that compared with the unstretched polymer film, the stretched PCL polymer film 200 exhibits a higher transmittance (˜90%), which advantageously promotes strong Raman excitation via laser interacting with the detected molecules to enhance Raman signals' intensity, as will be described below with reference to FIG. 7. After depositing a layer of Ag film at a thickness of 25 nm, the polymer SPR film 206 after the same stretching allows the formation of periodically plasmonic micro-ribbons perpendicularly to the elongation direction 205 (region 1), while the area of inter-ribbons is only composed of PCL polymer film (region 2), as shown in FIG. 2(b). This observation is also verified by chemical elemental mapping with energy-dispersive X-ray (EDX) spectroscopy, which will be described below with reference to FIG. 8. In the SPR effective region 1 with metallic hot-spots, unique phenomena were observed as shown in FIG. 2(c). A new type of large-area micro-ribbons (numeral 2) array parallel to the stretching direction 204 at a period of ˜1 μm is formed. On the ribbons (numeral 2), plenty of transgranular nanogaps (dark spots in FIG. 2(c)) are created at a dimension of tens of nanometers. Among neighbouring ribbons (numeral 2), there are many nanogrooves (numeral 1) at a width of ˜100 nm along the stretching direction 207.

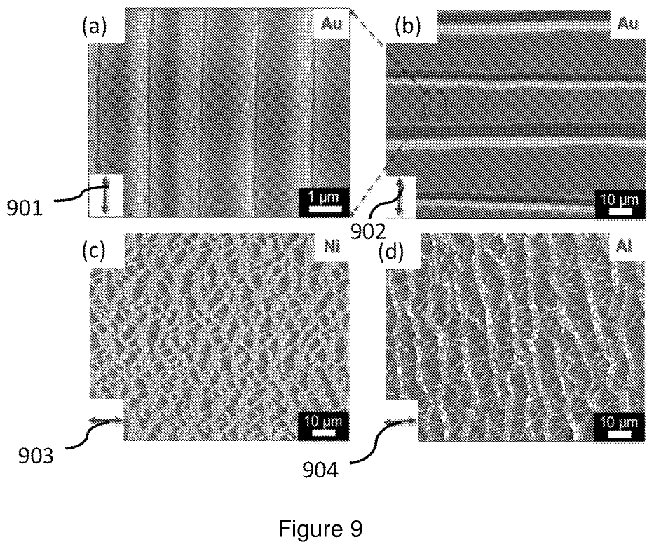

In order to further reveal the surface morphology of the stretched polymer SPR film 206, an atomic force microscope (AFM) is applied to further characterize the sample surface. It can be seen from FIG. 2(d) that micro-ribbons e.g. 208 array (compare also region 1 in FIG. 2(b)) demonstrates well-defined three-dimensional (3D) wave-shaped geometry at an average height of ˜110 nm. Meanwhile, similar experiments were carried out according to different embodiments to demonstrate the structures' formation of other three metal materials, including Ni, Al and Au at a thickness of 25 nm, deposited on PCL polymer films, after the stretching, the morphology of which are probably associated with brittleness and ductility of various metals as will be described below with reference to FIG. 9. In particular, Au, as one of the most frequently used materials for excellent plasmonic performance, can form similar nanostructures like Ag. However, the nanogaps' size of Au (average 10 nm) is a bit smaller than that of Ag (average 20 nm) at the same thickness, which is attributed to the higher ductility of gold being able to withstand a larger elongation.

In order to demonstrate the SERS capability of this polymer SPR film according to example embodiments, a self-assembled monolayer of 4-methylbenzenethiol (4-MBT)^{[45]} was adsorbed on the polymer SPR film and then Raman signals of the probing molecules were measured with a 514 nm laser as an excitation light source. As can be seen in FIG. 2 (e), the SERS signals (spectrum 210) are very weak (only ˜62 counts) for 1592 cm⁻¹ peak before the stretching, which are attributed to the flat Ag film deposited on PCL polymer being able to offer a few hot-spots to enhance Raman signals. However, after the stretching, the SERS signals (spectrum 212) reach to ˜630 counts, which are ˜10 times larger. This phenomenon is because the stretched polymer SPR film according to example embodiments advantageously leads to a much higher density of nanogaps among nanoparticles and nanogrooves, which function as hot-spots. These hot-spots with more intense local fields can contribute to much better SERS performance. Furthermore, the spot-to-spot average relative standard deviation (RSD) of SERS intensities at 1073 cm⁻¹ is 6.48%, indicating high homogeneity and reproducibility of the flexible SERS substrate according to example embodiments as shown in FIG. 2 (f), which enables its potential applications in quantitative analyses. The uniformity of the stretched polymer SPR film according to example embodiments was found to be superior to other flexible SERS substrates fabricated by lithographic methodologies.

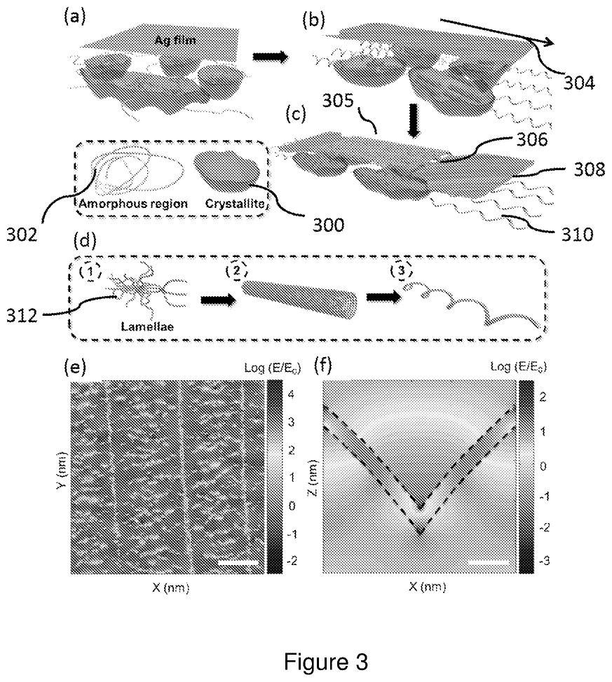

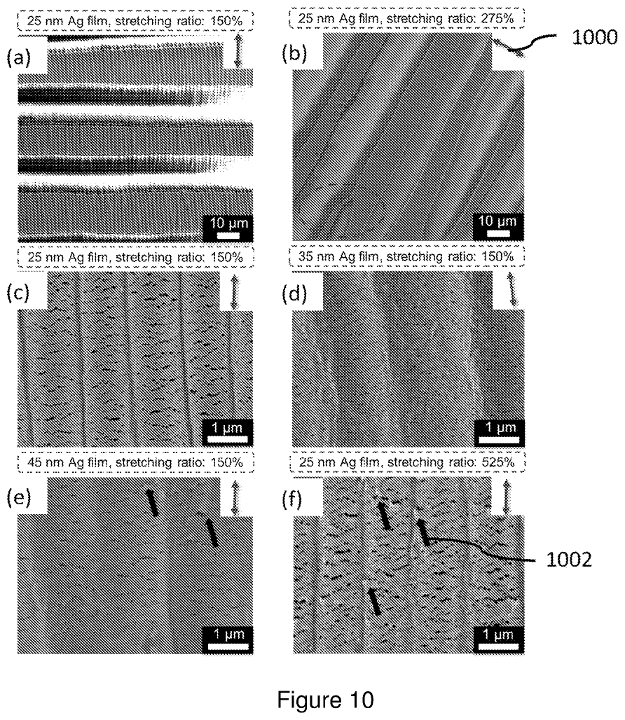

In the following, the mechanisms of nanostructures' formation on semi-crystalline PCL polymer films according to example embodiments, which are composed of crystallitic and amorphous phases, will be discussed with reference to FIG. 3. Upon applying a uniaxial stress, the crystallite and amorphous regions 300, 302, respectively, present an excellent tendency to orient along the stretching direction 304, compare FIGS. 3(a) and (b). After the yield strength, the dual-layered polymer SPR film 305 after the stretching forms plentiful tiny cracks e.g. 306 on the superficial Ag nanoparticle layer 308, while the beneath PCL layer 310 remains with intact integrity, due to a significant difference in the ductilities of the metal thin film 306 and the PCL layer 310. However, a continuous stretching leads to plastic deformation of the PCL layer 310, accounting for the observed formation of two distinct regions: PCL monolayer (in regions of the expanding cracks e.g. 306) and Ag/PCL dual layers elsewhere. The further increase of the plastic strain on the PCL monolayer results in a force propagating to the Ag/PCL dual layers and re-orientation of the PCL crystals e.g. 300 in these regions along the stretching direction 304. The PCL crystals e.g. 300 further experience a plastic strain due to their Poisson's ratio, which results in lateral shrinkage and increased distance among adjacent lamellaes e.g. 312 within a crystal e.g. 300, see e.g. FIGS. 3(c) and (d). Such deformation of PCL crystals e.g. 300 accounts for the observed formation of nanogrooves along the stretching direction 304 and transgranular nanogaps in the superficial Ag layer 308, respectively. After the polymer SPR film 305 is entirely deformed, the continued stretching of the polymer SPR film 305 gives rise to the splitting of Ag/PCL region due to the strain of PCL monolayer region to be near the break point and insufficient to support the sustained elongation of the polymer SPR film as will be described below with reference to FIG. 10. Moreover, further stretching of the polymer SPR film 305 initiates the Ag film to debond from the beneath PCL polymer film due to the larger tractions on the interface.^{[32]} It was also found that for Ag films thicker than 25 nm it is difficult to form nanogrooves and nanogaps, which is ascribed to the larger bending resistance of the thicker Ag film.

To further reveal the optical properties of the polymer SPR film 305 and identify the nature of the formation of hot-spots, finite-difference-time-domain (FDTD) simulation was applied to study the distributions of near-field electromagnetic fields. FIG. 3(e) depicts a two-dimensional (2D) electric field intensity map (Log scale) of the stretched polymer SPR film 305 at the Ag film's thickness of 25 nm in the region of micro-ribbons in Cartesian x-y plane at the excitation wavelength of 514 nm. The incident light is polarized along the stretching axis. The nanogaps resemble nanocavities to converge the incident photons, resulting in higher electromagnetic enhancement. The maximum simulated electric field intensity (E/E₀) is found to be ˜170 and the average one is ˜90. Meanwhile, V-shaped nanogrooves also act as plasmonic nanocavities, which can strongly focus incident electromagnetic wave into nanoscale gaps located at the groove tips under normal illumination in x-z plane, where the polarization of incident light is perpendicular to the stretching direction, as shown in the map in FIG. 3(f).^{[33,34]} These stretching-induced nanogaps and V-shaped-nanogrooves afford high-density hot-spots, which play an important role in confining incident photons as well as boosting Raman signals, according to example embodiments.

To calculate the electric field distribution of uniaxially stretched polymer SPR film according to example embodiments, the numerical FDTD method from Lumerical Solutions, Inc was applied to study the optical characteristic. A clear FESEM image of Ag coated polymer film after the stretching, according to an example embodiment, was imported into the FDTD software to create structures, followed by the scale definition. The polarized electromagnetic wave at the excitation wavelength of 514 nm with polarization along the uniaxially stretching direction was set to propagate normal to the structure surface. Perfectly matched layers (PML) were applied along z direction as boundary conditions to avoid the interference from the boundaries, while periodical boundary conditions (PBC) were applied in x and y directions. The electric field distributions were recorded by placing a 2D z-normal monitor in x-y plane on the top surface of the structure. Similarly, to achieve the electric field distributions of the nanogroove, a 2D y-normal monitor in x-z plane was employed. To achieve high resolution of electric field distribution, the mesh size region was set as 2.5×2.5×2.5 nm and the monitor is placed inside the reduced mesh size region.

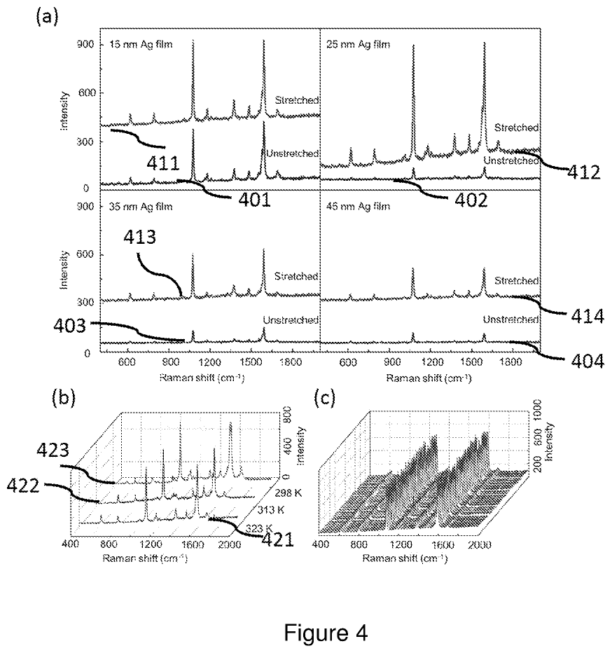

As mentioned above, in order to evaluate the SERS performance of the polymer SPR film according to example embodiments, a self-assembled monolayer of 4-methylbenzenethiol (4-MBT) was adsorbed on the polymer SPR film and then SERS signals of the probing molecules were measured with a 514 nm laser as an excitation light source. FIG. 4(a) compares the SERS performance of the PCL polymer film decorated with different thicknesses of Ag films before (spectra 401-404) and after (spectra 411 to 414) the stretching. It is found that when the thickness of Ag films reaches 25 nm, the SERS signal demonstrates the maximum enhancement after the stretching of our polymer SPR film from 4 cm to 10 cm, compare spectra 402 and 412. As can be seen, the SERS signals are very weak (only ˜62 counts) for 1580 cm⁻¹ peak before the stretching (spectrum 402), which are attributed to the flat Ag film deposited on PCL polymer being able to offer a few hot-spots to enhance Raman signals. However, after the stretching (spectrum 412), the SERS signals reach to ˜630 counts, which are ˜10 times larger. This phenomenon is believed to be because the stretched polymer SPR film leads to a much higher density of nanogaps among nanoparticles and nanogrooves, which function as plentiful hot-spots. These hot-spots with more intense local fields advantageously contribute to much better SERS performance according to example embodiments. For the SERS performance of polymer SPR film without the stretching, when the thickness of the Ag film is only 15 nm, non-continuous Ag films are formed on the flexible substrate due to the Volmer-Werber growth mode, resulting in higher intensity of SERS signals than that of thicker Ag films.^{[35]} However, at the thickness of 5 nm of Ag film, there are isolated Ag nanoparticles formed on the PCL polymer film. After the stretching, the distance between these adjacent nanoparticles become larger, leading to the weaker intensity of localized field among the nanogaps and then weaker SERS signals as will be described below with reference to FIG. 12.

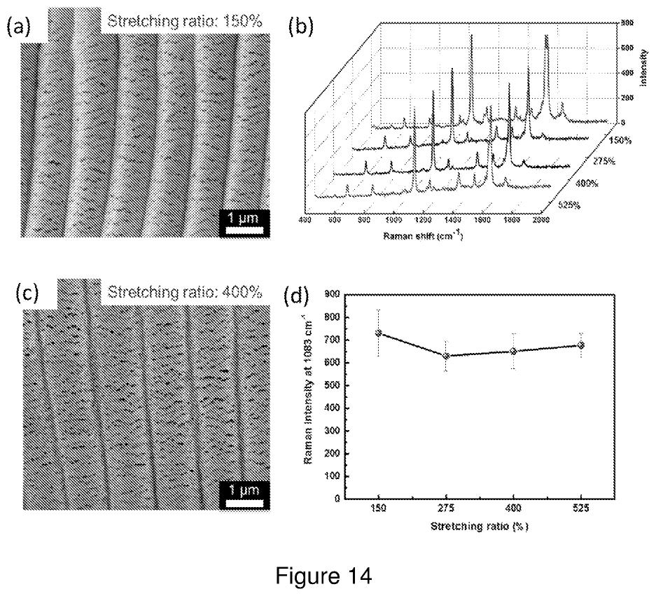

In SERS applications, it is greatly significant to develop a universally reliable and stable system to generate reproducible SERS substrates with high uniformity from batch to batch. In such a system, the framework of SERS substrates' stability is highly crucial. Their property is required to endure the variance of the temperature. To demonstrate the stability of the polymer SPR film according to example embodiments during the stretching, extensive experiments at different temperatures were performed from room temperature (298 K) to 323 K, as shown in FIG. 4(b). From the measured SERS spectra 421-423, it can be seen that the intensity of Raman signals has almost no degradation (9.62%), which shows the stable characteristic of the flexible SERS substrates according to example embodiments. Furthermore, the spot-to-spot (see spectra in FIG. 4(c)) average relative standard deviation (RSD) of intensities at 1073 cm⁻¹ is 6.48%, indicating high homogeneity and reproducibility of the flexible SERS substrate, which enables its potential applications in quantitative analyses. The uniformity of the stretched polymer SPR film was found to be superior to other flexible SERS substrates fabricated by lithographic methodologies (Table S1).^{[36-38]} Meanwhile, via increasing the stretching ratio of the polymer SPR film according to example embodiments, the intensity of SERS signals shows no obvious variation (6.47%), as will be described below with reference to FIG. 14. It is found that the stretching ratio of the polymer SPR film according to example embodiments can reach to ˜650% due to the excellent ductility of PCL polymer film, which demonstrates its batch-fabrication capability to satisfy the requirements of low-cost, single-use and easy-to-operate characteristics in lab-on-chip systems for POC applications.

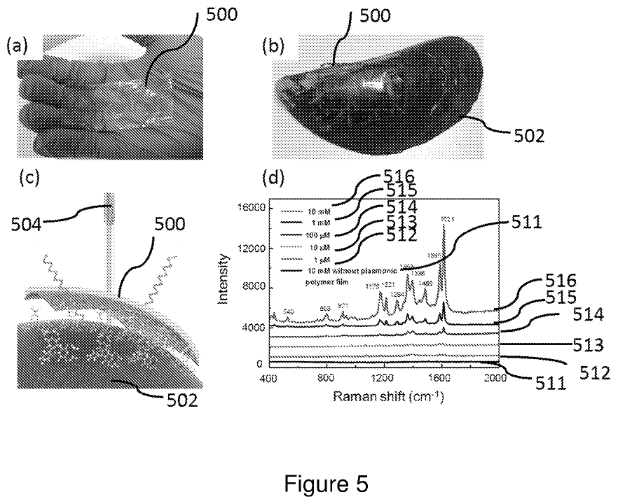

The polymer SPR film according to example embodiments with good flexibility and transparency is able to serve as an effective tool for in-situ, rapid and label-free identification of a wide variety of molecules. Different from the conventional rigid SERS substrates, the flexible plasmonic SERS substrates 500 according to example embodiments (photograph image of 8 cm×4 cm example embodiment shown in FIG. 5(a)) can be attached onto non-planer surfaces and collect their Raman signals from the back side of the SPR film. This capability was demonstrated with the stretched Ag deposited polymer film as SERS substrates 500 for in-situ detection of malachite green (MG) molecules on green mussel 502 surfaces, as shown in FIGS. 5(b) and (c).

Green mussels purchased from a supermarket and then washed with deionized water were immersed in various concentrations of malachite green (MG) from 10 mM to 1 μM at a step of 10 for 8 h and dried at room temperature. Then, a drop of ethanol (˜20 μL) is added on the front side with Ag nanostructures of flexible SERS film according to example embodiments, which is softly attached onto the green mussel's surface with MG molecules and the Raman signals are collected from the back side of the film. A Renishaw 2000 Raman imaging microscope equipped with a 514 nm continuous wave (CW) laser 504 was used in the characterization. The Raman signals were collected through a 50×(NA=0.8) microscope lens and detected by a thermoelectrically CCD array. The intensity of laser power was set as ˜0.15 mW at an acquisition time of 10 s and accumulation time of 1. The spectra resolution was 1 cm⁻¹.

Due to its functionality to control protozoan infections and fungal attacks associated with helminths on a variety of fish, MG has been widely applied in aquaculture and industries. However, it has the risk to pose potential problems on human health, such as organ damages and carcinogenic possibilities. As shown in FIG. 5(d), there are no Raman peaks observed after immersing the green mussel into 10 mM MG solution without attaching a polymer SPR film, see spectrum 511. While, with a stretched Ag deposited polymer film 500 seamlessly contacted with the non-planer surface of the green mussel, all characteristic Raman peaks of MG molecules are clearly distinguished, which are attributed to the high-density of hot-spots formed on the stretched plasmonic polymer film, leading to huge enhancement of SERS signals. In particular, a tremendous enhancement of Raman shift at 1621 cm⁻¹ is more evident related to the vibration mode of ring C—C stretching, the intensity of which decreases gradually with lowering concentration of MG solutions, compare spectra 511 to 516. The detection limit can be down to as low as 1 μM. This demonstrates a new non-invasive approach to realize in-situ chemical identification on non-planar surfaces and the ultra-thin polymer SPR film according to example embodiments is expected to access small corners of complex surface, such as carambola, which is very easy to hide and stay with residual pesticides.

The Example embodiments based on longitudinally stretching Ag/PCL composites using the new biodegradable and biocompatible semi-crystalline polymer can provide uniform hybrid nanostructures. Such stretched flexible and productive polymer SPR film with high-density of hot-spots affords a new route for in-situ detection of analytes residing on arbitrary topological surfaces, showing the potentials in environmental and food safety monitoring for POC diagnostics. Meanwhile, the stretching induced V-shaped nanogrooves can offer a variety of applications, such as efficient quantum emitter,^{[41]} adiabatic nanofocusing,^{[42]} nanophotonic circuitry^{[43]} and nano-opto-mechanics.^{[44] Stretching semi-crystalline polymer composite according to example embodiments can be extended towards other materials, such as gold (Au), alumina (Al), nickel (Ni), copper (Cu) or titanium (Ti), for other nano-photonic applications.}

Example embodiments of the present invention can provide biodegradable and flexible SERS substrates through an environmentally friendly PCL polymer film as the building block. Via irreversibly and uniaxially stretching polymer SPR film, high-density of nanogaps and nanogrooves array are simply created, resulting in an order of magnitude (˜10 times) enhancement of SERS signals than that of the unstretched polymer SPR film. The flexible polymer SPR film according to example embodiments can be intimately attached onto arbitrary shape surfaces of interest for in-situ detection of analytes. Furthermore, the polymer SPR film according to example embodiments exhibits highly stable and uniform SERS signals, making it feasible to generate reproducible SERS substrates from batch to batch. Meanwhile, the polymer SPR film according to example embodiments can be extended further through developing hybrid Au/Ag/PCL or metal/insulator/metal/PCL systems to realize higher performance of SERS enhancement. The polymer SPR films according to example embodiments with the characteristics of biodegradability and batch-fabrication have unprecedented opportunities to be integrated into portable Raman spectrometers for disposable applications as next-generation POC diagnostics, which are conceivable to penetrate into global markets and households in near future.

FIG. 6(a) to (d) show results of additional surface morphology investigations of the polymer SPR films deposited with Ag (thickness: 25 nm), according to an example embodiment. Specifically, FIG. 6(a) shows an SEM image before the stretching, while FIGS. 6(b) and (c) show SEM images after the stretching with tilt-view 45° and 90°, respectively. FIG. 6(d) shows an AFM image mapping of one micro-ribbon. The polymer SPR film was stretched from 4 cm to 10 cm at a width of 1 cm in this embodiment. Field Emission Scanning Electron Microscope ((FESEM, JEOL FEG JSM 7001F) was used for obtaining the SEM images to characterize the morphologies of the Ag coated PCL films before and after the uniaxial stretching, operating at 5 kV at a working distance of 6-8 mm. The elements' distribution was analyzed by energy-dispersive X-ray spectroscope (EDX, Oxford Instruments). A Tapping-mode Bruker SPM D3100V atomic force microscope (AFM) was applied for obtaining the AFM image to reveal the 3D morphology of the polymer SPR film after the stretching.

FIG. 7 shows transmission spectra of the PCL polymer film according to an example embodiment before (spectrum 700) and after (spectrum 702) the stretching. The dashed line 704 denotes the wavelength of 514 nm.

FIG. 8 (a) shows an SEM image of the stretched polymer SPR film according to an example embodiment. Again, region 1 denotes the SPR region (bi-layer PCL and Ag) and region 2 represents the PCL region. FIGS. 8 (b) and (c) show the EDX mapping of the polymer SPR film after the stretching according to an example embodiment to show the distributions of Ag and C, respectively. FIG. 8(d) shows a higher-resolution SEM image of the polymer SPR film (25 nm thick Ag film) after the stretching according to an example embodiment with corresponding EDX measurement to show the materials' constitutions in regions 1 and 2, respectively. The polymer SPR film is stretched from 4 cm to 10 cm at a width of 1 cm in this example embodiment. The red arrow 800 denotes the stretching direction.

As shown in FIGS. 8(a-c), along the stretching direction, there are two regions formed, including SPR region and PCL region. In the SPR region, the growth of Ag film follows the Volmer-Werber growth mode, which involves nucleation of isolated islands, coalescence of islands and thickening of Ag film^{[46]} The interaction of neighbouring islands is attracted by Van der Waals' force^{[46]} The stretching induced driving force results in the breakage of grain boundaries to allow the formation of transgranular nanogaps (FIG. 8(d)). Inside the nanogaps, a few nanoparticles (less than 5 nm) are observed, which were also characterized by EDX analyses

FIGS. 9(a) to (d) illustrate the surface morphology of various metallic materials deposited on the PCL polymer films, according to example embodiments, specifically FIGS. 9(a) and (b) Au, FIG. 9(c) Ni, and FIG. 9(d) Al. The thicknesses of the metallic films are 25 nm and the composite film is stretched from 4 cm to 10 cm at a width of 1 cm in these example embodiments. The red arrows 901 to 904 denote the stretching direction.

FIGS. 10(a) to (f) show SEM images of the polymer SPR film according to an example embodiment to investigate the stretching mechanisms. FIG. 10(a) shows a 25 nm Ag coated PCL film according to an example embodiment, stretching ratio: 150% (low magnification). FIG. 10(b) shows the same 25 nm Ag coated PCL film, stretching ratio: 275% (low magnification). FIG. 10(c) shows the same 25 nm Ag coated PCL film, stretching ratio: 150% (high magnification). FIG. 10(d) shows a 35 nm Ag coated PCL film according to an example embodiment, stretching ratio: 150% (high magnification). FIG. 10(e) shows a 45 nm Ag coated PCL film according to an example embodiment, stretching ratio: 150% (high magnification). FIG. 10(f) shows the 25 nm Ag coated PCL film, stretching ratio: 525% (high magnification). The width of each film is 1 cm. The arrows e.g. 1000 indicate the stretching direction. The dashed circle in FIG. 10(b) indicates the split of Ag/PCL regions. The debonding effect is marked by the arrows e.g. 1002 in FIGS. 10(e) and (f).

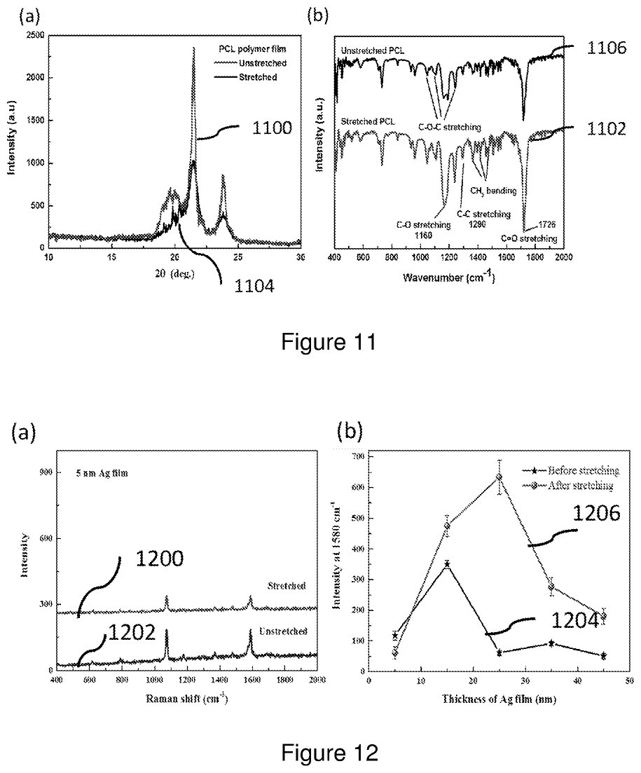

FIGS. 11(a) and (b) show XRD and FTIR spectra, respectively, of the stretched (spectra 1100, 1102) and unstretched (spectra 1104, 1106) PCL polymer films according to an example embodiment. As illustrated in FIG. 11(a), the PCL polymer film consists of amorphous and crystalline structures, which have three strong diffraction peaks at Bragg angles 2θ=21.49°, 21.8° and 23.81°, representing the (110), (111) and (200) planes of the orthorhombic crystal structure, respectively. After the uniaxial stretching of the PCL polymer film, the diminished broad peak at 19.78° and broadening of PCL (110) and (200) peaks indicate the reorientation of crystallite and amorphous regions upon the applied uniaxial stress. The FTIR spectra of PCL polymer film exhibit characteristic peaks of C═O stretching vibrations at 1726 cm⁻¹, C—O—C stretching vibrations at 1042, 1107 and 1233 cm⁻¹ and CH₂ bending modes at around 1360, 1395 and 1470 cm⁻¹. The bands at 1160 and 1290 cm⁻¹ are related to C—O and C—C stretching in the amorphous and in the crystalline phases, respectively. The increments of both peak intensities of amorphous and crystalline phases of the stretched film suggest a similar conclusion of reorientated crystallite and amorphous regions in the bulk film.

A CRAIC UV-VIS-NIR micro-spectrometer QDI 2010 was applied to obtain the transmittance spectra from 300 to 900 nm of polymer films. The Fourier transform infrared (FT-IR) spectra of PCL polymer film were obtained by using a Shimadzu IRPrestige-21FT-IR spectrophotometer. The spectra were recorded using 50 scans at 4 cm-1 resolution from 400 to 2000 cm⁻¹. Furthermore, the plasmonic composite were investigated by X-ray diffraction (XRD, X' Pert PRO MRD) with CuKα radiation at a voltage of 40 kV and current of 40 mA. The scan range was from 10° to 30° at a step size of 0.02° and time per step of 10 s. The optical constants of PCL polymer film were determined by using a variable angle spectroscopic ellipsometer at three different angles of incident light ranging from 65° to 75° at a step of 5°.

FIGS. 12(a) and (b) illustrates the influence of thickness of Ag film on PCL polymer film (stretched, spectrum 1200 and unstretched, spectrum 1202) on SERS performance, according to example embodiments. In FIG. 12(a) the thickness of 5 nm Ag film on PCL polymer film. In FIG. 12(b) the average SERS intensity at 1580 cm-1 Raman band at different thicknesses of Ag film before (plot 1204) and after (plot 1206) the stretching is shown. The polymer SPR films are stretched from 4 cm to 10 cm at a width of PCL film 1 cm in these example embodiments.

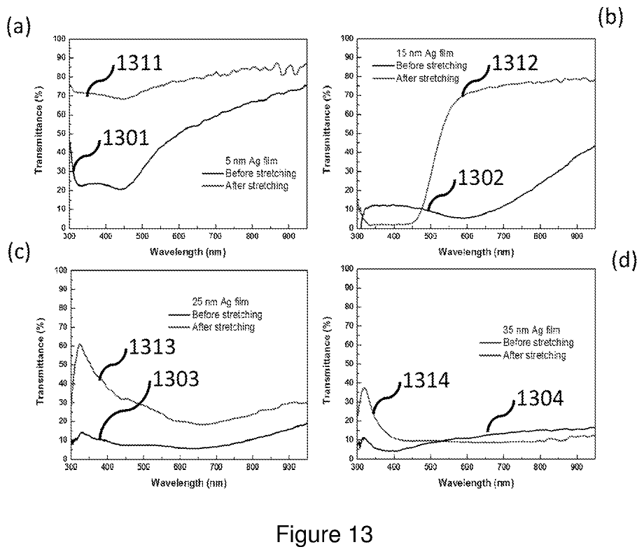

FIGS. 13(a) to (d) show Micro-UV-VIS transmission spectra of polymer SPR films at different thicknesses of Ag films before (spectra 1301-1304) and after (spectra 1311-1314) the stretching, according to example embodiments, specifically in FIG. 13(a) 5 nm, in FIG. 13(b) 15 nm, in FIG. 13(c) 25 nm, and in FIG. 13(d) 35 nm. The spectra were collected from the Ag/PCL region. The polymer SPR film is stretched from 4 cm to 10 cm at a width of 1 cm in these example embodiments.

FIGS. 14(a) to (d) illustrate the influence of the stretching ratio of the polymer SPR film on SERS performance, according to example embodiments. SEM images of the polymer SPR film at the stretching ratios of 150% and 400% are shown in FIGS. 14(a) and (b), respectively. FIG. 14(c) shows SERS spectra of 4-MBT molecules adsorbed on stretched polymer SPR films at various stretching ratios of 150%, 275%, 400% and 525%, respectively. FIG. 14(d) shows the average SERS intensity at 1083 cm⁻¹ Raman band at the different stretching ratios. All the thicknesses of Ag film were 25 nm at a width of 1 cm in these example embodiments.

As can be seen in FIGS. 14(a) to (d), the SERS signals show no obvious variation (6.47%) with the increasing stretching ratio, which is attributed to the larger extension of polymer SPR film primarily leading to the split of SPR region (compare FIG. 10(b)) rather than the widening of nanogaps. It was found that the stretching ratio of the polymer SPR film can reach to ˜650% due to the excellent ductility of PCL polymer film, according to example embodiments. The results indicate that the flexible SERS film according to example embodiments can be mass-produced by simply drawing polymer the SPR film without degrading SERS performance.

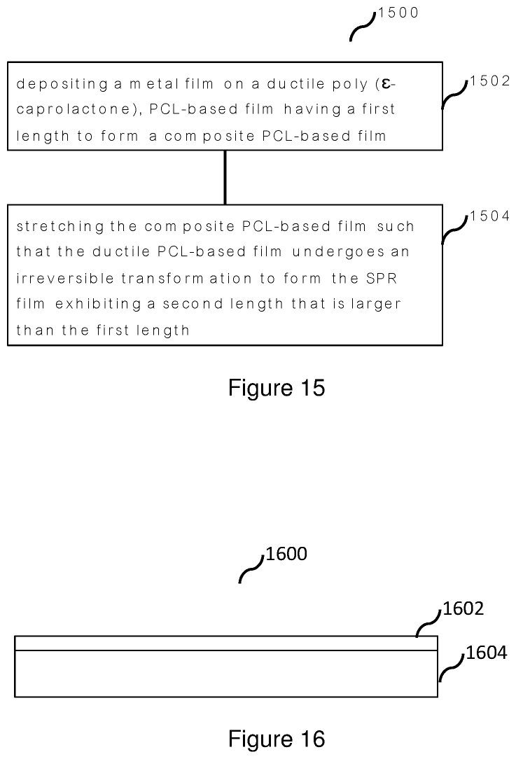

FIG. 15 shows a flowchart 1500 illustrating a method of fabricating a flexible surface plasmon resonance, SPR, film, according to an example embodiment. At step 1502, a metal film is deposited on a ductile poly (ε-caprolactone), PCL-based film having a first length to form a composite PCL-based film. At step 1504, the composite PCL-based film is stretched such that the ductile PCL-based film undergoes an irreversible transformation to form the SPR film exhibiting a second length that is larger than the first length.

The PCL-based film may be bio-compatible and/or bio-degradable.

The PCL-based film may comprise a semi-crystalline PCL polymer film. The semi-crystalline film may comprise crystallitic and amorphous phases.

The stretching may be performed such that the SPR film exhibits first and second regions, the first regions comprising the PCL-based film as a single layer and the second regions comprising the PCL-based film and the metal film as double layers.

The metal film in the SPR film may comprise plasmonic nanogaps and/or nanogrooves. The method may further comprise selecting a thickness of the metal film to tune a density of plasmonic nanogaps and/or nanogrooves.

The metal film may comprise one or more of a group consisting of Ag, Au, Ni, Cu, Ti and Al.

A ratio of the second length to the first length may be in the range from about 150% to about 525%.

A thickness of the metal film may be in a range from about 10 nm to about 50 nm.

The stretching may be performed uniaxially.

In one embodiment, a method of performing Surface enhanced Raman Spectroscopy, SERS, comprises using the SPR film fabricated from the method described above with reference to FIG. 15 as a SERS substrate.

FIG. 16 shows a schematic cross-sectional drawing illustrating a flexible surface plasmon resonance, SPR, film 1600 according to an example embodiment, comprising a metal film 1602 on a ductile poly (ε-caprolactone), PCL-based film 1604, wherein the ductile PCL-based film 1604 is in an irreversible transformation state in which a length of the ductile PCL-based film 1604 is enlarged compared to an unstretched state in which the metal film 1602 was deposited onto the ductile PCL-based film 1604.

The stretched SPR film 1600 may give rise to more than 10 times Surface enhanced Raman Spectroscopy, SERS signal enhancement in comparison with that of the unstretched SPR film.

The PCL-based film 1604 may be bio-compatible and/or bio-degradable.

The PCL-based film 1604 may comprise a semi-crystalline PCL polymer film. The semi-crystalline film may comprise crystallitic and amorphous phases.

The SPR film 1600 may exhibit first and second regions, the first regions comprising the PCL-based film 1604 as a single layer and the second regions comprising the PCL-based film 1604 and the metal film 1602 as double layers.

The metal film 1602 in the SPR film 1600 may comprise plasmonic nanogaps and/or nanogrooves.

A thickness of the metal film 1602 may be selected to tune a density of plasmonic nanogaps and/or nanogrooves.

The metal film 1602 may comprise one or more of a group consisting of Ag, Au, Ni, Cu, Ti and Al.

A ratio of the second length to the first length may be in the range from about 150% to about 525%.

A thickness of the metal film 1602 may be in a range from about 10 nm to about 50 nm.

The irreversible transformation state may be a result of uniaxially stretching.

In one embodiment, a Surface enhanced Raman Spectroscopy, SERS, system comprises the SPR film described above with reference to FIG. 16 as a SERS substrate.

Embodiments of the present invention provide flexible SERS films using environmentally friendly PCL polymer films as the building blocks. Via irreversibly and uniaxially stretching the composite film, high-density of nanogaps and nanogrooves arrays are created according to example embodiments, which advantageously result in an order of magnitude enhancement of SERS signals than that of the unstretched film. The stretched composite film according to example embodiments can be seamlessly attached onto any irregular surfaces for in-situ detection of chemical analytes. Furthermore, the polymer SPR film according to example embodiments advantageously exhibits highly uniform SERS signals, making it feasible to generate reproducible SERS substrates from batch to batch. The polymer SPR films according to example embodiments with the characteristics of biodegradability and batch-fabrication have many applications including to be integrated into portable Raman spectrometers for disposable applications as next-generation POC diagnostics. Non-limiting example applications include:
To realize in-situ detection of analytes by conformally attaching stretched flexible SERS film onto any arbitrary surfaces of interest.
To realize a simple way to fabricate flexible SERS substrates with low-cost, single-use and easy-to-operate characteristics.
To meet the requirement of environmental protection and sustainability.

Embodiments of the present invention can have one or more of the following features and benefits/advantages:

| Feature | Benefit/Advantage |
|---|---|
| Poly (ε-caprolactone) (PCL) film as a | Biodegradability, flexibility and |
| building block | high transparency |
| Irreversible and uniaxial stretching | High productivity |
| Stretching induced nanogaps and | To function as hot-spots to enhance |
| nanogrooves | Raman signals |

The above description of illustrated embodiments of the systems and methods is not intended to be exhaustive or to limit the systems and methods to the precise forms disclosed. While specific embodiments of, and examples for, the systems components and methods are described herein for illustrative purposes, various equivalent modifications are possible within the scope of the systems, components and methods, as those skilled in the relevant art will recognize. The teachings of the systems and methods provided herein can be applied to other processing systems and methods, not only for the systems and methods described above.

The elements and acts of the various embodiments described above can be combined to provide further embodiments. These and other changes can be made to the systems and methods in light of the above detailed description.

In general, in the following claims, the terms used should not be construed to limit the systems and methods to the specific embodiments disclosed in the specification and the claims, but should be construed to include all processing systems that operate under the claims. Accordingly, the systems and methods are not limited by the disclosure, but instead the scope of the systems and methods is to be determined entirely by the claims.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

### REFERENCES

[1] T. Cheng, Y. Zhang, W. Y. Lai, W. Huang, Adv. Mat. 2015, 27, 3349.
[2] J. Zhong, Y. Zhang, Q. Zhong, Q. Hu, B. Hu, Z. L. Wang, J. Zhou, ACS Nano 2014, 8, 6273.
[3] Y. Li, S. Luo, M. C. Yang, R. Liang, C. Zeng, Adv. Funct. Mat. 2016, 26, 2900.
[4] A. Kaushik, R. Kumar, S. K. Arya, M. Nair, B. Malhotra, S. Bhansali, Chem. Rev. 2015, 115, 4571.
[5] R. S. Golightly, W. E. Doering, M. J. Natan, ACS Nano 2009, 3, 2859.
[6] M. Irimia-Vladu, Chem. Soc. Rev. 2014, 43, 588.
[7] A. E. Cetin, A. F. Coskun, B. C. Galarreta, M. Huang, D. Herman, A. Ozcan, H. Altug, Light. Sci. Appl. 2014, 3, e122.
[8] O. Tokel, F. Inci, U. Demirci, Chem. Rev. 2014, 114, 5728.
[9] B. Zhang, M. Montgomery, M. D. Chamberlain, S. Ogawa, A. Korolj, A. Pahnke, L. A. Wells, S. Masse, J. Kim, L. Reis, Nature Mat. 2016, 15, 669.
[10] K. Kneipp, Y. Wang, H. Kneipp, L. T. Perelman, I. Itzkan, R. R. Dasari, M. S. Feld, Phys. Rev. Lett. 1997, 78, 1667.
[11] A. Campion, P. Kambhampati, Chem. Soc. Rev. 1998, 27, 241.
[12] S. A. Maier, Plasmonics: fundamentals and applications, Springer Science & Business Media, 2007.
[13] B. Sharma, R. R. Frontiera, A.-I. Henry, E. Ringe, R. P. Van Duyne, Mat. Today 2012, 15, 16.
[14] H. Jans, Q. Huo, Chem. Soc. Rev. 2012, 41, 2849.
[15] S. Chan, S. Kwon, T. W. Koo, L. P. Lee, A. A. Berlin, Adv. Mat. 2003, 15, 1595.
[16] L. Polavarapu, L. M. Liz-Marzán, Phys. Chem. Chem. Phys. 2013, 15, 5288.
[17] Q. Liu, J. Wang, B. Wang, Z. Li, H. Huang, C. Li, X. Yu, P. K. Chu, Biosens. Bioelectron. 2014, 54, 128.
[18] J. Chen, Y. Huang, P. Kannan, L. Zhang, Z. Lin, J. Zhang, T. Chen, L. Guo, Anal. Chem. 2016, 88, 2149.
[19] X. Liu, J. Wang, L. Tang, L. Xie, Y. Ying, Adv. Funct. Mat. 2016, 26, 5515.
[20] G. Zheng, L. Polavarapu, L. M. Liz-Marzán, I. Pastoriza-Santos, J. Perez-Juste, Chem. Commun. 2015, 51, 4572.
[21] H. Mitomo, K. Hone, Y. Matsuo, K. Niikura, T. Tani, M. Naya, K. Ijiro, Adv. Opt. Mat. 2016, 4, 259.
[22] H. Kang, C. J. Heo, H. C. Jeon, S. Y. Lee, S. M. Yang, ACS Appl. Mater. Interfaces 2013, 5, 4569.
[23] S. Kumar, D. K. Lodhi, P. Goel, Neeti, P. Mishra, J. P. Singh, Chem. Commun. 2015, 51, 12411.
[24] A. Lamberti, A. Virga, A. Angelini, A. Ricci, E. Descrovi, M. Cocuzza, F. Giorgis, RSC Adv. 2015, 5, 4404.
[25] Z. Zuo, K. Zhu, C. Gu, Y. Wen, G. Cui, J. Qu, Appl. Surf. Sci. 2016, 379, 66.
[26] W. Wu, L. Liu, Z. Dai, J. Liu, S. Yang, L. Zhou, X. Xiao, C. Jiang, V. A. Roy, Sci. Rep. 2015, 5, 10208.
[27] Y. Qian, X. Zhang, L. Xie, D. Qi, B. K. Chandran, X. Chen, W. Huang, Adv. Mat. 2016, 28, 9243.
[28] S. Shabahang, G. Tao, J. J. Kaufman, Y. Qiao, L. Wei, T. Bouchenot, A. P. Gordon, Y. Fink, Y. Bai, R. S. Hoy, A. F. Abouraddy, Nature 2016, 534, 529.
[29] T. Fang, W. Li, N. Tao, K. Lu, Science 2011, 331, 1587.
[30] C. L. Smith, A. H. Thilsted, C. E. Garcia-Ortiz, I. P. Radko, R. Marie, C. Jeppesen, C. Vannahme, S. I. Bozhevolnyi, A. Kristensen, Nano Lett. 2014, 14, 1659.
[31] C.-Y. Wang, H.-Y. Chen, L. Sun, W.-L. Chen, Y.-M. Chang, H. Ahn, X. Li, S. Gwo, Nature Commun. 2015, 6, 7734.
[32] N. Lu, Z. Suo, J. J. Vlassak, Acta Mater. 2010, 58, 1679.
[33] C. L. Smith, A. H. Thilsted, C. E. Garcia-Ortiz, I. P. Radko, R. Marie, C. Jeppesen, C. Vannahme, S. I. Bozhevolnyi, A. Kristensen, Nano Lett. 2014, 14, 1659.
[34] C. L. Smith, N. Stenger, A. Kristensen, N. A. Mortensen, S. I. Bozhevolnyi, Nanoscale 2015, 7, 9355.
[35] J. Perumal, K. V. Kong, U. S. Dinish, R. M. Bakker, M. Olivo, RSC Adv. 2014, 4, 12995.
[36] J. W. Jeong, M. M. P. Arnob, K. M. Baek, S. Y. Lee, W. C. Shih, Y. S. Jung, Adv. Mat. 2016, 28, 8695.
[37] Z. Li, G. Meng, Q. Huang, X. Hu, X. He, H. Tang, Z. Wang, F. Li, Small 2015, 11, 5452.
[38] J. Chen, Y. Li, K. Huang, P. Wang, L. He, K. R. Carter, S. R. Nugen, ACS Appl. Mat. Interfaces 2015, 7, 22106.
[39] S. Srivastava, R. Sinha, D. Roy, Aquat. Toxicol. 2004, 66, 319.
[40] J. Loos, T. Schimanski, J. Hofman, T. Peijs, P. Lemstra, Polymer 2001, 42, 3827.
[41] D. Martin-Cano, L. Martin-Moreno, F. J. Garcia-Vidal, E. Moreno, Nano Lett. 2010, 10, 3129.
[42] T. Sondergaard, S. M. Novikov, T. Holmgaard, R. L. Eriksen, J. Beermann, Z. Han, K. Pedersen, S. I. Bozhevolnyi, Nature Commun. 2012, 3, 969.
[43] S. P. Burgos, H. W. Lee, E. Feigenbaum, R. M. Briggs, H. A. Atwater, Nano Lett. 2014, 14, 3284.
[44] A. S. Shalin, P. Ginzburg, P. A. Belov, Y. S. Kivshar, A. V. Zayats, Laser Photon. Rev. 2014, 8, 131.
[45] K. Seo, E. Borguet, J. Phys. Chem. C 2007, 111, 6335.
[46] A. Saedi, M. J. Rost, Nature Commun. 2016, 7, 10733.

1. A method of fabricating a flexible surface plasmon resonance, SPR, film comprising the steps of:
depositing a metal film on a ductile poly (ε-caprolactone), PCL-based film having a first length to form a composite PCL-based film; and
stretching the composite PCL-based film such that the ductile PCL-based film undergoes an irreversible transformation to form the SPR film exhibiting a second length that is larger than the first length.

2. The method of claim 1, wherein the PCL-based film is bio-compatible and/or bio-degradable.

3. The method of claim 1, wherein the PCL-based film comprises a semi-crystalline PCL polymer film.

4. The method of claim 3, wherein the semi-crystalline film comprises crystallitic and amorphous phases.

5. The method of claim 1, wherein the stretching is performed such that the SPR film exhibits first and second regions, the first regions comprising the PCL-based film as a single layer and the second regions comprising the PCL-based film and the metal film as double layers.

6. The method of claim 1, wherein the metal film in the SPR film comprises plasmonic nanogaps and/or nanogrooves, and the method optionally comprises selecting a thickness of the metal film to tune a density of plasmonic nanogaps and/or nanogrooves.

7. (canceled)

8. The method of claim 1, wherein the metal film comprises one or more of a group consisting of Ag, Au, Ni, Cu, Ti and Al and/or wherein a ratio of the second length to the first length is in the range from about 150% to about 525%, and/or wherein a thickness of the metal film is in a range from about 10 nm to about 50 nm.

9. (canceled)

10. (canceled)

11. The method of claim 1, wherein the stretching is performed uniaxially.

12. A method of performing Surface enhanced Raman Spectroscopy, SERS, comprising using the SPR film fabricated from the method of claim 1 as a SERS substrate.

13. A flexible surface plasmon resonance, SPR, film comprising:
a metal film on a ductile poly (ε-caprolactone), PCL-based film; and
wherein the ductile PCL-based film is in an irreversible transformation state in which a length of the ductile PCL-based film is enlarged compared to an unstretched state in which the metal film was deposited onto the ductile PCL-based film.

14. The SPR film of claim 13, wherein the stretched SPR film gives rise to more than 10 times Surface enhanced Raman Spectroscopy, SERS signal enhancement in comparison with that of the unstretched SPR film.

15. The SPR film of claim 13, wherein the PCL-based film is bio-compatible and/or bio-degradable.

16. The SPR film of claim 13, wherein the PCL-based film comprises a semi-crystalline PCL polymer film.

17. The SPR film of claim 16, wherein the semi-crystalline film comprises crystallitic and amorphous phases.

18. The SPR film of claim 13, wherein the SPR film exhibits first and second regions, the first regions comprising the PCL-based film as a single layer and the second regions comprising the PCL-based film and the metal film as double layers.

19. The SPR film of claim 13, wherein the metal film in the SPR film comprises plasmonic nanogaps and/or nanogrooves.

20. The SPR film of claim 19, further wherein a thickness of the metal film is selected to tune a density of plasmonic nanogaps and/or nanogrooves.

21. The SPR film of claim 13, wherein the metal film comprises one or more of a group consisting of Ag, Au, Ni, Cu, Ti and Al and/or wherein a ratio of the second length to the first length is in the range from about 150% to about 525%, and/or wherein a thickness of the metal film is in a range from about 10 nm to about 50 nm.

22. (canceled)

23. (canceled)

24. The SPR film of claim 13, wherein the irreversible transformation state is a result of uniaxially stretching.

25. A Surface enhanced Raman Spectroscopy, SERS, system comprising the SPR film of claim 13 as a SERS substrate.
